(19) United States
(12) Patent Application Publication
(10) Pub. No.: US 2004/0144318 A1
(43) Pub. Date: Jul. 29, 2004

(54) Device for ceramic-type coating of a substrate

(76) Inventors: Thomas Beck, Kirchberg (DE); Thomas Weber, Stuttgart (DE); Alexander Schattke, Stuttgart (DE); Sascha Henke, Weil der Stadt (DE)

Correspondence Address: KENYON & KENYON, ONE BROADWAY, NEW YORK, NY, 10004, US

(21) Appl. No.: 10/470,400

(22) PCT Filed: Jan. 18, 2002
(86) PCT No.: PCT/DE02/00138

(30) Foreign Application Priority Data
Feb. 2, 2001 (DE) 101 04 611.1

(51) Int. Cl. C23C 16/00; H05H 1/24

(52) U.S. Cl. 118/723 R; 427/569

(57) ABSTRACT

A device is proposed for the ceramic-type coating of a substrate (2), means being provided for depositing a material (5, 7), especially by using a plasma (8), on a surface of the substrate (2), which, in contrast to the related art, allows a ceramic coating (3) of comparatively temperature-sensitive substrates (2). According to the present invention, this is achieved in that an energy source that differs from a material source (4, 6) of the material (5, 7) provided for the coating, is provided for the locally defined energy input into the material (3, 5, 7, 8) present in front of and/or on the surface.

The present invention is directed to a device for the ceramic-type coating of a substrate according to the definition of the species in claim 1.

### BACKGROUND INFORMATION

Ceramic-type layers having excellent mechanical, electrical, optical and chemical properties may be produced, above all, by using plasma methods. Corresponding methods have been utilized for quite some time to coat tools so as to extend their service life, or to increase the lifetime of mechanically stressed components or machine elements, such as shafts, bearing components, pistons, gear wheels or the like, and also to apply decorative designs on surfaces. A multitude of metallic compounds are used in this context, such as high-melting oxides, nitrides and carbides of aluminum, titanium, zirconium, chromium or silicon. In particular the titanium-based layer systems, such as TiN, TiCN or TiAlN layer systems, are used primarily on machining tools as wear protection.

Also known are super-hard materials, which represent a combination of a nano-crystalline (nc), hard transition metal nitride MeₙN with amorphous (a) Si₃N₄. In such nc-MeN/a-SI₃N₄ composite materials, the hardness, for instance, significantly increases with decreasing crystallite size below approximately 4 to 5 nanometer and, at 2 to 3 nanometer, approaches that of a diamond. In particular the polypnase structure of the coating yields layers having a hardness of >2500 HV, for instance, at comparatively low brittleness.

Corresponding layers are produced, in particular, by plasma-activated chemical vapor deposition (PACVD) methods at temperatures of approximately 500 to 600 degrees Celsius. In particular, the comparatively high temperature of the substrate, and consequently the coating, allows a diffusion of amorphously deposited coating components, and thus the formation of nanocrystallites in an amorphous matrix.

Disadvantageous in this case is, however, that comparatively temperature-sensitive materials, such as numerous plastics or composites or alloys with a tendency to structure changes, and the like, cannot be coated.

### SUMMARY OF THE INVENTION

In contrast, the object of the present invention is to propose a device for the ceramic-type coating of a substrate, means being provided for depositing a material, especially by means of a plasma, on a surface of the substrate, which, in contrast to the related art, also allows a ceramic-type coating of comparatively temperature-sensitive substrates.

Starting from a device of the type indicated in the introduction, this objective is attained by the characterizing features of claim 1.

The measures indicated in the dependent claims permit advantageous embodiments and further developments of the present invention.

To that effect, a device according to the present invention is distinguished in that an energy source is provided for the locally defined energy input into the material present in front of and/or on the surface, the energy source differing from a material source of the material provided for the coating.

According to the present invention, this makes it possible to realize, in particular within one layer, a nanostructured, ceramic, high-quality layer system, which includes nanostructured metal crystallites having a crystal size of up to approximately 100 nm, consisting, for example, of MeO, MeN or MeC, in a wider matrix structure, which is amorphous, crystalline or metallic and consists, for example, of amorphous silicon compounds or the like.

The nanostructured layer includes at least one crystalline hard material phase. This substantially increases, in particular, the layer hardness, so that a hardness of over 4000 HV may be achieved when TiO crystallites are inserted. At the same time, the brittleness of the ceramic layers is reduced, especially by the nanostructure. The entire layer system may be single- or multi-layered, chemical and partially graduated and/or ungraduated. Furthermore, a breaking-in layer may be realized by a carbonaceaous covering layer.

Moreover, corresponding nano-composites may be deposited in an advantageous manner, for instance at substrate temperatures T<400 degrees C., preferably at temperatures T<250 degree Celsius, so that even comparatively temperature-sensitive substrates are able to be coated.

According to the present invention, the supply of kinetic energy to increase the surface mobility and, thus, to diffuse the deposited material components, is preferably implemented via an additional plasma excitation, so that, compared to the related art, in particular substantially higher ion densities may be achieved, which is also illustrated by a corresponding change in the color and the brightness of the plasma. With the aid of the plasma excitation or the higher ion density and, thus, higher energy density, the initially amorphously deposited particles obtain enough energy for diffusion on the substrate so as to be able to form on the substrate TiO crystallites having nanometer size, for instance. For this purpose, too, additional plasma sources are conceivable, which are operated, in particular, at a lower pressure, in a fine vacuum, for example.

Especially as a result of the high ion energy or ion density, in particular by smashing already produced micro-crystallites, their build-up is prevented and the advantageous nanocrystalline growth promoted at the same time. In this way, any number of different three-dimensional components, among others, are able to be coated in an appropriate manner.

In a special specific embodiment of the present invention, the energy is input into the material present on the surface, so that once again the initially amorphously deposited particles have enough energy available to diffuse on the substrate, so as to form, for example, cubical, hexagonal, metallic or other crystallites of nano-size on the substrate.

A microwave unit is advantageously provided for the energy input, so that, for example during sputtering, the ion density of the material may be increased by supplementary ionization. In this way, advantageous ionization densities of approximately 10¹⁰ to 10¹³ ions per cm³ may be realized, so that the initially amorphously deposited material has enough energy available to diffuse on the substrate. To this end, microwave radiation is preferably provided for the so-called electron cyclotron resonance excitation (ECR).

In a special specific embodiment of the present invention, an ion-source unit is provided for the energy input, so that, once again, an advantageous plasma excitation or increase in the ion density is realized, thereby allowing the diffusion of the initially amorphously deposited material on the substrate.

For the energy input according to the present invention, it is alternatively also possible to provide a DC- or RF-excited hollow cathode unit, for example, or a similar device. These devices have in common the locally defined energy input according to the present invention, preferably into the material that is present in front of the substrate surface.

Furthermore, a UV unit or the like is provided in an advantageous manner. With the aid of these units, additional kinetic energy is preferably input into the material present on the substrate surface to diffuse the particles initially amorphously deposited on the substrate.

In a special further refinement of the present invention, a cooling device is provided to cool the substrate, thereby ensuring in an advantageous manner that the greatest possible lowering of the substrate temperature is realized. It is especially due to this measure that more temperature-sensitive substrates are able to be coated.

The cooling device is preferably realized by means of a metallic or other substrate carrier having good thermal conductivity. Moreover, an advantageous coolant may flow through the cooling device, so that a further lowering of the substrate temperature may be achieved.

In a special specific embodiment of the present invention, a voltage source is provided to generate an electric field between the material source and the substrate. This ensures that, for instance, an advantageous potential profile is produced between the material source and the substrate and that a charging of the substrate, especially by an RF-substrate voltage or a bias voltage, is prevented.

### EXEMPLARY EMBODIMENT

An exemplary embodiment of the invention is shown in the drawings and is elucidated in greater detailing the following description with reference to the figures.

The individual figures show:

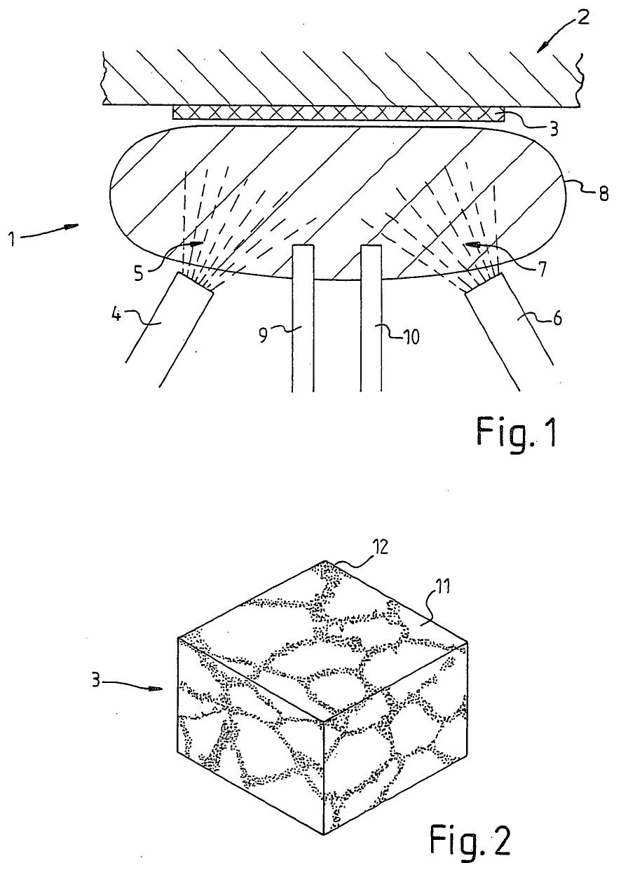

FIG. 1 a schematic structure of a device according to the present invention;

FIG. 2 a schematic 3-D representation of a cut-away portion of a coating produced according to the present invention;

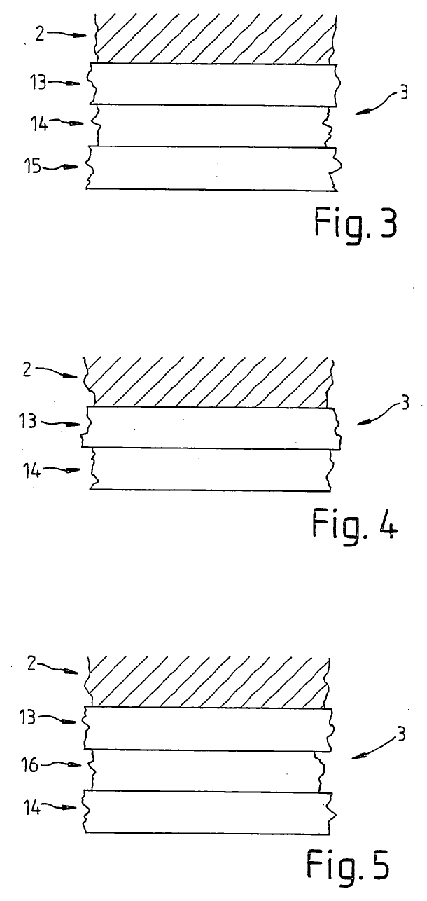

FIG. 3 a schematic representation of a multi-layer coating produced according to the present invention;

FIG. 4 a schematic representation of another multi-layer coating produced according to the present invention; and

FIG. 5 a schematic representation of a third multi-layer coating produced according to the present invention.

FIG. 1 schematically depicts a cut-away portion of a coating chamber 1 during a coating operation. In the process, a layer 3 is deposited on a substrate 2 at a chamber pressure of approximately 10⁻³ to 10⁻² mbar. A sputter source 4 atomizes a first material 5. A second material 7 is correspondingly atomized by a sputter source 6, either simultaneously with material 5 or in a time-staggered manner. According to the present invention, the locally defined energy input into both materials 5, 7 is carried out using plasma 8, which is schematically shown in FIG. 1. The plasma production, or the plasma excitation as well, is implemented, for instance, with the aid of an ECR microwave source (not shown further). Argon, helium, oxygen or the like being used as plasma gas. Plasma 8 is produced, for instance, by microwave radiation of 2.45 GHz frequency with an output as a function of the layer thickness of preferably 1 kW. The microwave radiation is coupled in, for instance, via a rod antenna (not shown further).

Sputter source 4 may include a metal, a metal-oxide target or a mixed target, for example, the metal being titanium, chromium, copper, zirconium or the like.

With the aid of a gas supply 9 and 10, two different reaction gases may be apportioned as desired during the coating. For instance, oxygen may be charged into coating chamber 1 by gas supply 9 in order to produce oxidic ceramic layers. Should a sputter source 4 be used with a metal-oxide target, oxidic ceramic layers may also be produced without gas supply 9 supplying oxygen.

Sputter source 6 may include a silicon target and/or a carbon target, for example, so that sputter source 6 allows the formation of the amorphous matrix, such as silicon nitride or the like, in particular by nitrogen supplied by gas supply 10. Alternatively, gas supply 10 may supply other gases as well, so that other matrices may be produced, too, if needed.

Experience has shown that, for the most part, the reaction of the sputter components first occurs on the substrate. According to the present invention, plasma 8 inputs additional energy into the atomized or deposited particles with the aid of the ECR-microwave source, without the substrate being heated to any significant degree. In this way, the substrate temperature may be kept comparatively low. Due to the energy input by the ECR-microwave source, particles having nanometer size, such as titanium-oxide particles, are formed in coating 3 on the substrate by diffusion of the initially amorphously deposited particles. As a result, the high temperatures of the substrate, which lead to the nanostructured coating being formed according to the related art, are not required, so that even temperature-sensitive substrates may be coated according to the present invention.

According to the present invention, the coating is scalable as desired, without the substrate, for example, having to be used as electrode to densify the deposited coating. However, a special specific embodiment of the present invention includes a voltage source supplying an RF-bias voltage, for example, at the substrate. This mainly prevents, in particular, a charging of substrate 2, so that specifically the deposition of materials 5, 7 is not detrimentally changed, even over a comparatively longer coating period.

FIG. 2 illustrates a schematic, three-dimensional cut-away portion of a layer 3 having at least two multicomponent phases 11, 12, nanocrystallites 11 being integrated in an amorphous, refractory network 12. For instance, nanocrystallites 11 may be TiO, TiN, ZrN, ZrO, TiC, SiC, carbon crystallites or corresponding nanocrystallites 11 and a multitude of mixtures thereof, having particle sizes in the range of 5 to 20 nm. According to the present invention, the proportion of the surface volume in the overall volume is very high, and the boundary surfaces between nanocrystallites 11 and amorphous matrix 22 are comparatively sharp.

FIG. 3 schematically illustrates a layer structure of a coating 3 produced according to the present invention, with nanoscalar multi-layer coating 3 having been deposited on substrate 2. Coating 3 includes an adhesion promoter 13, which may optionally be applied and, for instance, is made up of a metallic layer, such as a titanium adhesion layer having a thickness of approximately 300 nm. As next layer 14, for instance, a layer according to FIG. 2 may be deposited, i.e., an amorphous silicon-nitride layer 12, for example, with nanoscalar titanium oxide- and/or carbon particles 11. Subsequently, for instance a cover layer 15 may optionally be applied, which preferably consists of amorphous carbon.

In addition to nearly planar substrates, the present invention also allows three-dimensional components, such as drills or the like, to be coated with an appropriate nanoscalar multi-layer coating 3.

The three-layered coating structure ensures an excellent adhesion of the super-hard ceramic metal-oxide layer 14 on substrate 2, especially when using adhesion promoter 13. Cover layer 15 ensures a high friction coefficient at a similar hardness, for example, so that, in particular, the friction characteristic of the nanostructured layer is improved during a breaking-in phase of mechanically stressed components or machine elements, such as shafts, bearing components, pistons, gear wheels or the like, and also of the two friction partners, or over the entire service life of the two friction partners.

As an alternative to the layer structure according to FIG. 3, a layer structure according to FIG. 4 may be provided. In this case, corresponding to FIG. 3, adhesion promoter 13 is optionally provided and a layer 14, which may include, for instance, an amorphous carbon network 12 with nanoscalar titanium-oxide particles 11.

According to FIG. 5, an alternative layer structure may be provided, which again includes an adhesion promoter 13, to be applied optionally, and an amorphous carbon layer 16, as well as a layer 14 with an amorphous silicon-nitride layer 12 and nanoscalar titanium-oxide particles 11. For instance, it is possible to deposit nanostructured metal-oxide layers 14 on diamond-type carbon layers 16 as well, in order to improve the breaking-in characteristics of wear-protection layers having a lower friction coefficient, for example.

Basically, especially nanostructured metal-oxide layers 14, with or without insertions or upper cover layer 15, are able to be used as Ear-protection layer or highest collective loadings with novel multifunctional properties. For example, due to their anti-stick characteristics and advantageous friction properties, these may be used as dry lubricant layers for the finishing of high-grade steel, aluminum or the like. Furthermore, the self-cleaning properties of titanium-oxide layers may be combined with anti-scratch properties.

In general, oxidic ceramic layers are advantageous since they possess high chemical inertia, are optically transparent and have a lower friction coefficient than nitride layers, for example. However, until now ceramic oxide layers have found only limited use in production, primarily because of the more delicate and more reactive process control than in the case of nitride layer systems. The stoichiometric oxygen content may be adjusted in this case by regulating the optical emission, for example. At the same time, oxidic ceramics stand out in use because of their excellent friction characteristics as well as high chemical stability and high layer hardnesses.

Corresponding to FIG. 1, it is basically also possible to produce, for example, chromium-oxide nanoparticles in a hollow cathode (not shown further). By the addition of silicon nitride through silicon sputtering and the addition of nitrogen gas, given simultaneous supplementary ionization by a microwave-wave source or high-current ion source, nc-CrOx/a-SiNx, for example, may be produced. Optionally, it is possible to subsequently apply a carbon layer 15 again so as to improve the break-in characteristics of corresponding components. According to the present invention, it is generally possible to supply nanocrystalline powder material to an ion source, or to have it synthesized thereby.

### LIST OF REFERENCE NUMERALS

1 coating chamber

2 Substrate

3 Layer

4 Sputter source

5 Material

6 Sputter source

7 Material

8 Plasma

9 Gas supply

10 Gas supply

11 Nanocrystallites

12 Network

13 Adhesion promoter

14 Layer

15 Cover layer

16 C-layer

What is claimed is:

1. A device for the ceramic-type coating of a substrate (2), means being provided for depositing a material (5, 7), in particular by using a plasma (8), on a surface of the substrate (2),
wherein an energy source that differs from a material source (4, 6) of the material (5, 7) provided for the coating, is provided for the locally defined energy input into the material (5, 7) present in front of and/or on the surface.

2. The device as recited in claim 1, wherein a microwave unit is provided for the energy input.

3. The device as recited in one of the preceding claims, wherein an ion-source unit is provided for the energy input.

4. The device as recited in one of the preceding claims, wherein a hollow cathode unit is provided for the energy input.

5. The device as recited in one of the preceding claims, wherein a UV-unit is provided for the energy input.

6. The device as recited in one of the preceding claims, wherein a cooling device is provided to cool the substrate (2).

7. The device as recited in one of the preceding claims, wherein a voltage source is provided to generate an electric field between the material source and the substrate (2).

8. A method for producing a ceramic-type coating (3) of a substrate (2), a material (5, 7) being deposited on a surface of the substrate 2), in particular by using a plasma (8), wherein a device as recited one of the preceding claims is used.

9. The method as recited in claim 8,
wherein a locally defined energy input, which differs from the material input, is provided into the material (5, 7) present in front of and/or on the surface of the material (5, 7).

10. The method as recited in one of the preceding claims, wherein a diffusion is provided of the material (5, 7) present on the surface so as to form particles having nanometer size.
